(19) United States
(12) Patent Application Publication
(10) Pub. No.: US 2023/0221471 A1
(43) Pub. Date: Jul. 13, 2023

(54) DISPLAY APPARATUS, AND OPTICAL DEVICE

(71) Applicant: Panasonic Intellectual Property Management Co., Ltd., Osaka (JP)

(72) Inventors: Jun ARAYA, Kyoto (JP); Shinji MASUDA, Osaka (JP); Masaaki OHNISHI, Kyoto (JP); Ryouji ONISHI, Osaka (JP); Masaomi SHIBATA, Hyogo (JP)

(21) Appl. No.: 18/001,028

(22) PCT Filed: Jun. 25, 2021
(86) PCT No.: PCT/JP2021/024079

§ 371 Date: Dec. 7, 2022

(30) Foreign Application Priority Data
Jun. 30, 2020 (JP) 2020-113182

(51) Int. Cl. G02B 5/00

(52) U.S. Cl. CPC G02B 5/005

(57) ABSTRACT

A display apparatus includes: a display including a display surface on which an image is displayed; and a decorative layer that is arranged on the display surface side of the display and includes a base layer and a design layer each formed to cover the display surface. The base layer includes a light diffusing material. A plurality of microholes are formed through the base layer. The design layer is formed to cover the plurality of microholes and a non-opening portion of the base layer.

### CROSS-REFERENCE OF RELATED APPLICATIONS

This application is the U.S. National Phase under 35 U.S.C. § 371 of International Patent Application No. PCT/JP2021/024079, filed on Jun. 25, 2021, which in turn claims the benefit of Japanese Patent Application No. 2020-113182, filed on Jun. 30, 2020, the entire disclosures of which Applications are incorporated by reference herein.

### TECHNICAL FIELD

The present disclosure relates to a display apparatus and an optical device.

### BACKGROUND ART

The display surface of a display apparatus, such as a liquid crystal display, includes a display region for displaying images and a peripheral edge region where accompanying elements such as a wiring pattern are provided. A decorative film may be used in the peripheral edge region to hide such accompanying elements from the user (see, for example, Patent Literature (PTL) 1).

### CITATION LIST

### Patent Literature

[PTL 1] Japanese Unexamined Patent Application Publication No. 2014-115306

### SUMMARY OF INVENTION

### Technical Problem

Depending on the application of the display apparatus, the display apparatus being invisible (not visible) when not displaying any images may be desirable. One configuration considered for achieving such a display apparatus is to provide the decorative sheet described in PTL 1 on the entire display surface including the display region and the peripheral edge region of a liquid crystal display (one example of a display). This makes the display apparatus less visible to the user, since the user will see the decoration on the decorative sheet when the display apparatus is not displaying images.

However, such a decorative sheet contains pigment, for example, which may diffuse the image light from the display surface when images are displayed. This can cause the images displayed by the display apparatus to appear blurry, i.e., the quality of the displayed images may decrease. Although it is possible to inhibit the blurring of images by forming through-holes through the decorative sheet, this reduces the design quality of the decorative sheet. In other words, conventionally, it has been difficult to both inhibit a reduction in design quality and inhibit a reduction in image quality.

In view of this, the present disclosure provides, for example, a display apparatus that can inhibit a reduction in design quality as well as inhibit a reduction in image quality.

### Solution to Problem

A display apparatus according to one aspect of the present disclosure includes: a display including a display surface on which an image is displayed; and a decorative layer that is arranged on a display surface side of the display and includes a base layer and a design layer each formed to cover the display surface. The base layer includes a light diffusing material, and a plurality of openings are formed through the base layer. The design layer is formed to cover the plurality of openings and a non-opening portion of the base layer.

An optical device according to one aspect of the present disclosure includes: an optical functional unit including at least one of a display that displays an image or a light receiving unit configured to receive light; and a decorative layer that includes a base layer and a design layer each formed to cover a front surface of the optical functional unit, and is arranged on a front surface side of the optical functional unit. The base layer includes a light diffusing material, and a plurality of openings are formed through the base layer. The design layer is formed to cover the plurality of openings and a non-opening portion of the base layer.

### Advantageous Effects of Invention

With, for example, the display apparatus according to one aspect of the present disclosure, it is possible to inhibit a reduction in design quality as well as inhibit a reduction in image quality.

### BRIEF DESCRIPTION OF DRAWINGS

FIG. 1 is an exploded perspective view schematically illustrating the general configuration of a display apparatus according to an embodiment of the present disclosure.

FIG. 2 is a cross-sectional view schematically illustrating a cross-sectional configuration of the display apparatus according to an embodiment of the present disclosure.

FIG. 3 is a block diagram illustrating the functional configuration of the display apparatus according to an embodiment of the present disclosure.

FIG. 4 illustrates the configuration of a base layer according to an embodiment of the present disclosure.

FIG. 5 is a diagram for illustrating a first experiment according to an embodiment of the present disclosure.

FIG. 6 illustrates the characteristics of a film used in the first experiment according to an embodiment of the present disclosure.

FIG. 7 illustrates the results of the first experiment according to an embodiment of the present disclosure.

FIG. 8 is a diagram for illustrating a second experiment according to an embodiment of the present disclosure.

FIG. 9 illustrates the results of the second experiment according to an embodiment of the present disclosure.

FIG. 10 is a flowchart illustrating one example of the manufacturing method of a decorative sheet according to an embodiment of the present disclosure.

FIG. 11 is a diagram for illustrating one example of the manufacturing method of the decorative sheet according to an embodiment of the present disclosure.

FIG. 12A is a diagram for illustrating the non-display mode in Application Example 1 of the display apparatus according to an embodiment of the present disclosure.

FIG. 12B is a diagram for illustrating the display mode in Application Example 1 of the display apparatus according to an embodiment of the present disclosure.

FIG. 13A is a diagram for illustrating the non-display mode in Application Example 2 of the display apparatus according to an embodiment of the present disclosure.

FIG. 13B is a diagram for illustrating the display mode in Application Example 2 of the display apparatus according to an embodiment of the present disclosure.

FIG. 14A is a diagram for illustrating the non-display mode in Application Example 3 of the display apparatus according to an embodiment of the present disclosure.

FIG. 14B is a diagram for illustrating the display mode in Application Example 3 of the display apparatus according to an embodiment of the present disclosure.

### DESCRIPTION OF EMBODIMENTS

### Underlying Knowledge Forming the Basis of the Present Disclosure

Prior to describing the embodiments of present disclosure, the underlying knowledge forming the basis of present disclosure will be explained.

As described in the Technical Problem section, the decorative sheet contains pigment, which may diffuse the image light from the display. From the viewpoint of inhibiting the diffusion of such image light, a plurality of through-holes (openings) may be formed through the decorative sheet. For example, when the decorative sheet has a stacked structure of a design layer and a base layer, through-holes may be formed through the design layer and the base layer.

The formation of through-holes may cause a reduction in image quality, such as a narrowing of the viewing angle of the display apparatus. In addition, from the viewpoint of inhibiting blurring of images, increasing the number of through-holes will fade the design of the decorative sheet (for example, the color will become lighter), which reduces design quality. Increasing the number of through-holes also makes the display more visible when images are not being displayed. In this way, conventionally, it has been difficult to both inhibit a reduction in design quality and inhibit a reduction in image quality.

In view of this, as a result of diligent consideration with respect to a display apparatus that can both inhibit a reduction in design quality and inhibit a reduction in image quality, the inventors of the present application have devised the display apparatus described below.

Hereinafter, embodiments will be described in detail with reference to the drawings. The embodiments described below each show a general or specific example. The numerical values, shapes, materials, elements, the arrangement and connection of the elements, steps, order of the steps, etc., in the following embodiments are mere examples, and therefore are not intended to limit the scope of the present disclosure. Among elements in the following embodiments, those not recited in any one of the independent claims are described as optional elements.

Note that the respective figures are schematic drawings, and are not necessarily precise illustrations. In the figures, elements that are essentially the same have the same reference signs, and duplicate description is omitted or simplified.

In the present specification and the figures, the X-axis, the Y-axis, and the Z-axis represent the three axes in a three-dimensional orthogonal coordinate system. In the embodiments, the Y-axis is the axis orthogonal to the display surface of the display (for example, parallel to the optical axis of the display). The X-axis and Z-axis are orthogonal to the Y-axis, for example. The display surface is, for example, parallel to the plane formed by the X-axis and Z-axis. As used in the present specification, a front view means, for example, a view from the Y-axis direction.

In the present specification, terms indicating relationships between elements such as “parallel”, “the same”, or “equal”, terms indicating shapes of elements such as “rectangular”, and numerical ranges refer not only to their strict meanings, but encompass a range of essentially equivalents, such as a range of deviations of a few percent.

### Embodiment

### [1. Configuration]

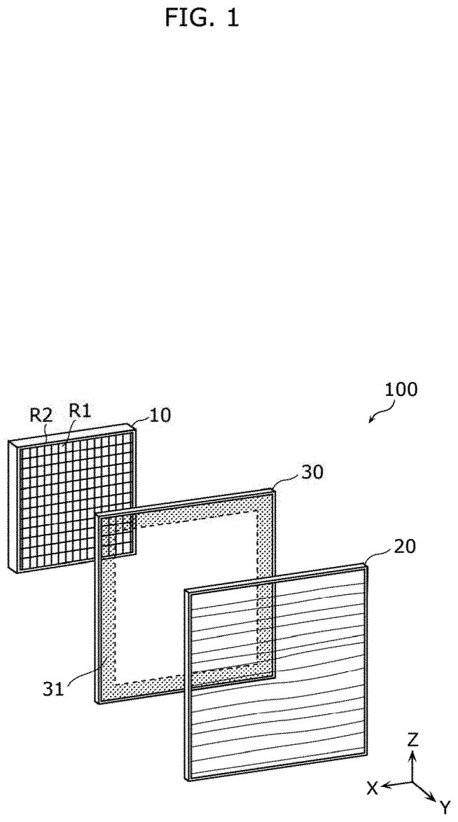

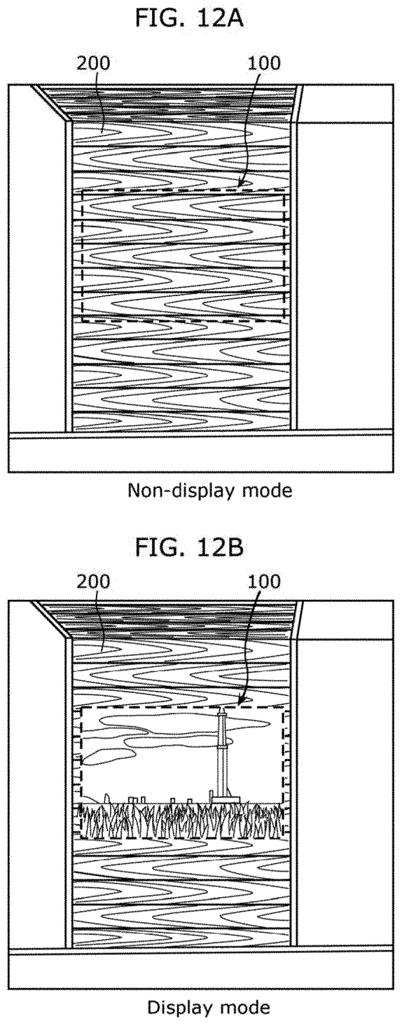

First, the configuration of display apparatus 100 according to the present embodiment will be described with reference to FIG. 1 through FIG. 4. For example, display apparatus 100 is used mounted to an object (for example, a wall). For example, display apparatus 100 is an embedded display apparatus that is embedded in an object. The following describes an example in which the object is a wood tone wall (see, for example, FIG. 12A), but the object is not limited to this example.

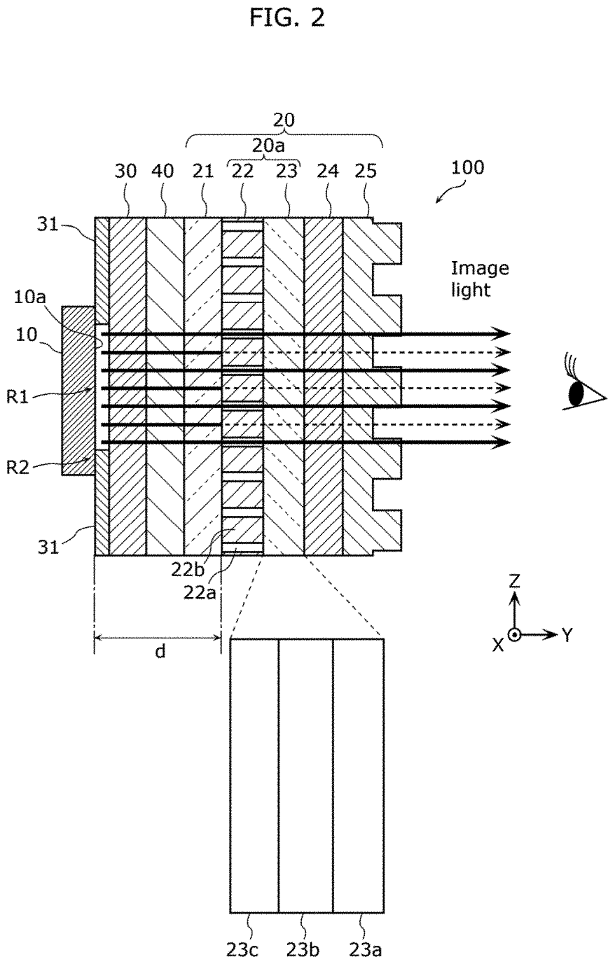

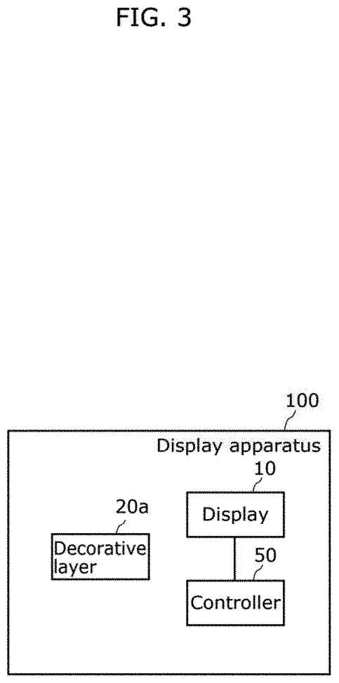

FIG. 1 is an exploded perspective view schematically illustrating the general configuration of display apparatus 100 according to the present embodiment. FIG. 2 is a cross-sectional view schematically illustrating a cross-sectional configuration of display apparatus 100 according to the present embodiment. FIG. 3 is a block diagram illustrating the functional configuration of display apparatus 100 according to the present embodiment. In FIG. 1, only display 10, decorative sheet 20, and transparent plate 30 are illustrated among the elements included in display apparatus 100.

As illustrated in FIG. 1 through FIG. 3, display apparatus 100 includes display 10, decorative sheet 20, transparent plate 30, diffusion layer 40, and controller 50. As illustrated in FIG. 1 and FIG. 2, display 10, transparent plate 30, and decorative sheet 20 are arranged in the listed order. More specifically, transparent plate 30 and decorative sheet 20 are arranged in the listed order on the display surface 10a side of display 10. Among the elements of display apparatus 100, at least display 10 should be embedded in the object. Here, embedded means that at least display 10 is located inside the object. Display apparatus 100 is embedded and arranged in the object such that the user can see decorative sheet 20. Display surface 10a is one example of the front surface.

Display apparatus 100 is arranged, for example, so that decorative sheet 20 is flush with the surface of the object. Stated differently, display apparatus 100 may be mounted so that it is embedded within the object such that decorative sheet 20 is flush with the surface of the object.

Display 10 includes display surface 10a, and displays images on display surface 10a. Display 10 includes a plurality of pixels. For example, display 10 is, but not limited to, a liquid crystal display or an electroluminescent (EL) display. Display 10 may be, for example, a light emitting diode (LED) display in applications where an increased luminance of the image to be displayed in display apparatus 100 is desired. As used herein, the term “image” includes still and moving images.

Display 10 includes display region R1 for displaying images and peripheral edge region R2 around display region R1. Display region R1 is, for example, the region in which the plurality of pixels are arranged. For example, the plurality of pixels are arranged in two dimensions (for example, in the X-axis and Z-axis directions). The plurality of pixels are arranged at an even pitch. Peripheral edge region R2 is, for example, the region in which accompanying elements such as wiring patterns are provided. Display 10 is one example of the optical functional unit.

In the present embodiment, display 10 is exemplified as, but not limited to, being smaller than decorative sheet 20 and transparent plate 30 when viewed from the front.

Decorative sheet 20 is provided to conceal (hide) display apparatus 100 when display apparatus 100 is embedded in the object. Decorative sheet 20 is light-transmissive, is arranged on the display surface 10a side of display 10, and is decorated according to the appearance of the object. The decoration is applied to the entire surface of decorative sheet 20, for example, but may be applied partially. As used herein, the term “appearance” includes, for example, the pattern, the color tone, the gloss, and the texture of the object. The term “appearance” may also include the shape of the surface of the object.

For example, decorative sheet 20 is provided to cover both display region R1 and peripheral edge region R2 of display 10. In the present embodiment, since decorative sheet 20 is larger than display 10 when viewed from the front, it is also provided to cover the area surrounding display 10. The decoration applied to decorative sheet 20 is applied, for example, in regions corresponding to each of display region R1, peripheral edge region R2, and the surrounding regions.

The decoration applied to decorative sheet 20 should be, for example, a decoration that makes display apparatus 100 and the object appear as an integral unit when display apparatus 100 is embedded in the object (for example, the decoration should make it difficult to see that display apparatus 100 is present). The decoration applied to decorative sheet 20 should be, for example, a decoration that harmonizes with the interior of the room the object is in. For example, if the object is a wall, display apparatus 100 should be embedded in the wall, and when the wall is viewed while display 10 is not displaying an image, the decoration should make display apparatus 100 appear to be the wall. In the present embodiment, since the object is exemplified as a wood tone wall, decorative sheet 20 is decorated with the same wood tone. Note that the decoration of decorative sheet 20 is not limited to wood tone. The decoration may be, for example, white luster tone, stainless steel tone, or something else.

More than one type of decoration may be applied to decorative sheet 20. For example, decorative sheet 20 may have different decorative patterns in display region R1, peripheral edge region R2, and the surrounding regions.

Decorative sheet 20 is arranged on the frontmost surface of display apparatus 100, for example. When display apparatus 100 is embedded in the object, the user sees decorative sheet 20.

As illustrated in FIG. 2, decorative sheet 20 includes, in order from the display 10 side, film 21, base layer 22, design layer 23, film 24, and textured layer 25. Base layer 22 and design layer 23 are sandwiched between the pair of films 21 and 24 in decorative sheet 20. Base layer 22 and design layer 23 together form decorative layer 20a.

The pair of films 21 and 24 serve as the base films of decorative sheet 20, and are made of a light-transmissive resin material or the like. For example, the pair of films 21 and 24 are made of polyethylene terephthalate (PET), polycarbonate (PC), or polymethylmethacrylate/acrylic resin (PMMA). The pair of films 21 and 24 may be transparent, for example. Note that one of the pair of films 21 and 24 may be omitted.

Base layer 22 is arranged between display surface 10a and design layer 23, and is used to adjust the overall hue, shade, etc., of decorative sheet 20. In the present embodiment, base layer 22 is formed on film 21. Base layer 22 can be said to be a layer for inhibiting display 10 from being visible from the outside of display apparatus 100. If the decoration of decorative sheet 20 is wood tone, base layer 22 is formed including, for example, brown ink. Base layer 22, for example, is formed uniformly in hue and thickness. For example, no designs are formed on base layer 22, but this example is non-limiting.

Base layer 22 includes a light diffusing material. Base layer 22 is formed by printing, for example, using ink or paint containing pigment (one example of the light diffusing material). In other words, base layer 22 contains pigment. Therefore, when image light enters base layer 22 it is diffused by the pigment. In other words, base layer 22 has light diffusing properties. Stated differently, base layer 22 is not transparent. This blurs the displayed image. In the present disclosure, a plurality of microholes 22a are formed in base layer 22 to inhibit the blurring of images. For example, among the individual elements of decorative sheet 20, microholes 22a are only formed in base layer 22. Microholes 22a are formed through base layer 22, and are one example of the openings. Stated differently, a plurality of openings are formed through base layer 22. Microholes 22a are also one example of a transmissive portion that transmits image light.

Microholes 22a constitute, for example, an air layer or a transparent resin layer. The portion of the image light from display 10 that passes through microholes 22a is therefore less likely to be diffused. This can inhibit the blurring of images by base layer 22. The portion of the image light from display 10 that is incident on base layer 22 (for example, incident on non-opening portion 22b of base layer 22) is diffused by pigment or the like. Therefore, from the viewpoint of inhibiting blurring of images, the transmittance of non-opening portion 22b should be low. For example, the transmittance of non-opening portion 22b is lower than that of microholes 22a. For example, the transmittance of non-opening portion 22b is preferably less than or equal to 5%, and more preferably less than or equal to 3%. Non-opening portion 22b may block the image light.

The transmittance of non-opening portion 22b can be adjusted by the pigment content ratio, thickness, etc. The transmittance of non-opening portion 22b should be uniform throughout the entire base layer 22, for example. For example, the transmittance of non-opening portion 22b refers to the total light transmittance.

In decorative sheet 20 according to the present embodiment, among base layer 22 and design layer 23, microholes 22a are formed only in base layer 22. Since base layer 22 contains pigment, etc., it is considered to have a greater effect on the blurring of images among the elements of decorative sheet 20. This configuration can therefore effectively inhibit the blurring of images while also inhibiting a reduction in the design quality of decorative sheet 20. Stated differently, display apparatus 100 can both achieve the desired design quality of decorative sheet 20 and achieve clear images.

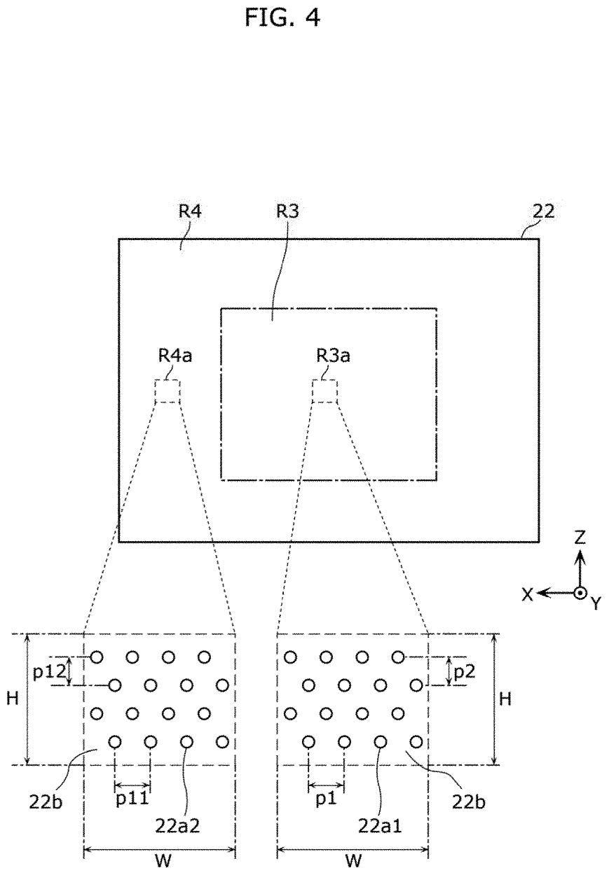

Next, the configuration of base layer 22 will be described with reference to FIG. 4. FIG. 4 illustrates the configuration of base layer 22 according to the present embodiment.

As illustrated in FIG. 4, base layer 22 includes image region R3 in which images are projected when displaying images, and peripheral region R4 surrounding image region R3. Image region R3 is, for example, in the front view, the region of display region 10 where images can be displayed, and is a region that overlaps display region R1. Image region R3 can also be said to be the region corresponding to display surface 10a. Stated differently, image region R3 is the region through which the image light is transmitted. Peripheral region R4 is, for example, a region that includes peripheral edge region R2 in the front view, and is a region that is not related to the display region of images but is visible to the user. For example, peripheral region R4 may be the region that overlaps light-shielding layer 31 illustrated in, for example, FIG. 1. In the present embodiment, peripheral region R4 is the area surrounding image region R3 in the front view. For example, peripheral region R4 is a region that does not result in the display of images by the image light. Image region R3 and peripheral region R4 are static regions.

As illustrated in the enlarged view of region R3a, a plurality of microholes 22a1 are formed in image region R3. For example, microholes 22a1 are formed uniformly throughout the entire image region R3. As illustrated in the enlarged view of region R4a, a plurality of microholes 22a2 are formed in peripheral region R4. For example, microholes 22a2 are formed uniformly throughout the entire peripheral region R4. Microholes 22a2 are thus formed in base layer 22 even in peripheral region R4 where the image light from display region 10 does not pass through. The sizes of regions R3a and R4a are equal; for example, regions R3a and R4a have width W and height H.

For example, the plurality of microholes 22a1 are formed in region R3a at an even pitch. For example, the plurality of microholes 22a1 are formed at pitch p1 in the X-axis direction and pitch p2 in the Z-axis direction. In the example in FIG. 4, 16 microholes 22a1 are formed at an even pitch.

For example, the plurality of microholes 22a2 are formed in region R4a at an even pitch. For example, the plurality of microholes 22a2 are formed at pitch p11 in the X-axis direction and pitch p12 in the Z-axis direction. In the example in FIG. 4, 16 microholes 22a2 are formed at an even pitch.

If the ratio of the area occupied by microholes 22a to a given area (for example, the area of the region whose width is W and height is H) is defined as the aperture ratio of the given area, the first aperture ratio, which is the aperture ratio of microholes 22a1 in area R3a, should be between 5% and 20%, inclusive. For example, the first aperture ratio and the second aperture ratio, which is the aperture ratio of microholes 22a2 in region R4a, should each be between 5% and 20%, inclusive. An aperture ratio greater than or equal to 5% allows for the display of images at the target brightness. If the aperture ratio is lower than 5%, the image light transmitted through microholes 22a (specifically, microholes 22a1) is reduced, making it difficult to display images at the target brightness. An aperture ratio less than or equal to 20% inhibits a reduction in the design quality of decorative sheet 20. For example, it is possible to inhibit the color in decorative sheet 20 from becoming too light (and thus fading the design). Stated differently, it is possible to inhibit display 10 from being visible from outside display apparatus 100.

The difference between the first aperture ratio of microholes 22a1 in region R3a and the second aperture ratio of microholes 22a2 in region R4a should be within a given difference (for example, within 5%). For example, the first aperture ratio and the second aperture ratio should be the same. For example, the first aperture ratio and the second aperture ratio may be made to be the same by making pitch p1 and pitch p11 the same, pitch p2 and pitch p12 the same, and microholes 22a1 and microholes 22a2 the same size. In other words, the plurality of microholes 22a may be uniformly formed in base layer 22.

Each of pitches p1, p2, p11, and p12 should be the same as the pixel pitch of display 10 or a constant multiple of the pixel pitch. From the viewpoint of inhibiting moiré, each of pitches p1, p2, p11, and p12 should be the same as the pixel pitch of display 10.

Although each of the first and second aperture ratios is exemplified above as being between 5% and 20%, inclusive, if the difference in appearance of image region R3 and peripheral region R4 in the non-display mode is within the desired range, at least one of the first and second aperture ratios may be less than 5% or greater than 20%. For example, if the first and second aperture ratios are equal, the aperture ratio may be less than 5% or greater than 20%.

Although each of the first and second aperture ratios is exemplified above as being between 5% and 20%, inclusive, if a layer that emphasizes the color of decorative sheet 20, such as a half mirror, or a layer that helps hide display 10, such as a smoke film, is arranged between decorative sheet 20 and display 10, each of the first and second aperture ratios may be greater than 20%. The first and second aperture ratios may be less than or equal to 60%, for example.

Although microholes 22a are exemplified as being formed at an even pitch in each of image region R3 and peripheral region R4, microholes 22a are not limited to this example. In at least one of image region R3 and peripheral region R4, microholes 22a may be formed at a random pitch. For example, in each of image region R3 and peripheral region R4, microholes 22a may be randomly formed. In such a case as well, the first and second aperture ratios should be the same from the viewpoint of inhibiting the deterioration of the appearance of decorative sheet 20 in the non-display mode.

For example, the front view diameter of microhole 22a is, but not limited to, several to several hundred micrometers. At least one microhole 22a may have a different diameter than other microholes 22a.

Although microholes 22a are exemplified as having a circular front view shape in each of image region R3 and peripheral region R4, microholes 22a are not limited to this example. The front view shape of microholes 22a is not limited to any particular shape, and may be oval, rectangular, polygonal, line shaped, grid shaped, etc. The front view shapes of microholes 22a1 and 22a2 may be the same or different from each other.

Referring again to FIG. 2, design layer 23 is a decorative design layer formed of a material such as transparent resin ink containing pigment or paint. The decorative pattern of design layer 23 is determined according to the appearance of the object in which display apparatus 100 is embedded. For example, the decorative pattern may have the same color tone or pattern as the color tone or pattern of the object in which display apparatus 100 is embedded. Design layer 23 is light-transmissive.

Design layer 23 is arranged between base layer 22 and film 24, and covers the surface of base layer 22 on the opposite side relative to the surface on the display 10 side (i.e., covers the Y-axis positive side surface of base layer 22). Design layer 23 is provided to cover each of image region R3 and peripheral region R4 of base layer 22. Design layer 23 is provided to cover each of the plurality of microholes 22a and non-opening portion 22b in each of image region R3 and peripheral region R4. Stated differently, there are no openings in design layer 23 that penetrate design layer 23. Thus, by not forming openings in design layer 23, i.e., by the design on decorative sheet 20 not being interrupted, a reduction in the design quality of decorative sheet 20 can be inhibited compared when design layer 23 has openings.

In the present embodiment, design layer 23 is a stacked structure of first design layer 23a, second design layer 23b, and third design layer 23c. Stated differently, design layer 23 is configured so that the user sees one design in three layers. The number of layers in design layer 23 is not particularly limited; one or more layers are sufficient. First design layer 23a, second design layer 23b, and third design layer 23c are one example of the pattern layers.

When design layer 23 includes a plurality of layers, at least one of the plurality of layers should be provided to cover each of microholes 22a and non-opening portion 22b of base layer 22. Stated differently, among the plurality of layers, microholes may be formed in layers other than the at least one layer. For example, these microholes are formed at positions overlapping with microholes 22a in base layer 22 in the front view. For example, the plurality of microholes formed in layers other than the at least one layer may overlap (for example, in one-to-one correspondence) with the plurality of microholes 22a in base layer 22 in the front view.

From the viewpoint of further enhancing design quality, when design layer 23 includes a plurality of layers, each of the layers should be provided to cover each of microholes 22a and non-opening portion 22b of base layer 22. In other words, each of the layers should be formed without breaks (for example, without openings) throughout the entire area of base layer 22.

Design layer 23 is formed on the display 10 side (i.e., the Y-axis negative side) surface of film 24 by printing or other means using ink containing pigment or paint.

Decorative layer 20a is thus arranged on the display surface 10a side of display 10, and includes base layer 22 and design layer 23, each of which is formed to cover display surface 10a. Each of base layer 22 and design layer 23, which together form decorative layer 20a, is formed to cover display surface 10a.

Textured layer 25 is light-transmissive and is an optical functional layer formed on the surface of film 24 on the opposite side relative to the surface on the display 10 side (i.e., formed on Y-axis positive side surface of film 24). Textured layer 25 may function as part of the decorative pattern. For example, the design may be formed by design layer 23 and textured layer 25. Textured layer 25 may, for example, function to improve the visibility of at least one of the images displayed by display apparatus 100 or the design. Textured layer 25 may, for example, function to diffusely reflect or reduce the reflection of outside light incident on display apparatus 100 from outside display apparatus 100. For example, textured layer 25 may also function to diffuse and emit image light to inhibit moiré from occurring in the image.

Textured layer 25 may be a layer with recesses formed by embossing, etc., an anti-glare (AG) film, or a layer formed by applying, drying, curing, etc., a coating liquid containing resin components, particles, and solvent on film 24 by a known coating method. The particles may be inorganic particles, such as silica or alumina or the like, or organic particles. Note that textured layer 25 need not be provided.

Transparent plate 30 is a plate-shaped member arranged between display 10 and decorative sheet 20. Transparent plate 30 is made of resin or glass. By including transparent plate 30, display 10 can be effectively protected and decorative sheet 20 can be kept flat, compared to when a film is included instead of transparent plate 30. By maintaining the flat surface of decorative sheet 20, an advantage of an improved appearance of the design can be expected.

The transmittance of transparent plate 30 should be high. For example, the transmittance of transparent plate 30 is, but not limited to greater than or equal to 80%. Transparent plate 30 is arranged so as to oppose image region R3 and peripheral region R4 of base layer 22. For example, transparent plate 30 may be the same size as decorative sheet 20 in the front view.

In the present embodiment, light-shielding layer 31 is provided on the display 10 side (i.e., Y-axis negative side) surface of transparent plate 30, in a region corresponding to peripheral region R4 in the front view. Light-shielding layer 31 is provided so as not to block image light. Light-shielding layer 31 is provided, for example, to surround display region R1. Light-shielding layer 31, for example, is provided so as to avoid the region corresponding to display region R1, but may partially overlap display region R1.

Light-shielding layer 31 need only be arranged between display 10 and decorative layer 20a, and is not limited to being formed on the surface of transparent plate 30 on the display 10 side.

Transparent plate 30 should have a thickness (a length in the Y-axis direction) less than or equal to 3 mm when display apparatus 100 includes diffusion layer 40. This can inhibit the blurring of images caused by a longer distance between display 10 and decorative sheet 20.

Light-shielding layer 31 inhibits the interior space of the object to which display apparatus 100 is mounted from being visible when display apparatus 100 is not displaying an image, i.e., light-shielding layer 31 blocks light from entering this interior space from outside display apparatus 100. This makes it possible for light-shielding layer 31 to give decorative sheet 20 the same or similar appearance in the region overlapping display 10 and the region not overlapping display 10 (for example, in image region R3 and peripheral region R4) when display apparatus 100 viewed while not displaying an image. Light-shielding layer 31 can make it difficult for display 10 to be recognized as being inside the object.

For example, light-shielding layer 31 is formed by printing using a black coating agent, but this example is not limiting; light-shielding layer 31 may be realized with light-shielding tape, for example. Note that light-shielding layer 31 need not be provided.

Diffusion layer 40 is arranged between display 10 and decorative layer 20a, and is a light diffusing layer that diffuses image light from display 10. In the present embodiment, diffusion layer 40 is arranged between transparent plate 30 and film 21. Diffusion layer 40 can provide a slight diffusion effect to the image light from display 10. From the viewpoint of inhibiting moiré, diffusion layer 40 should have a haze value greater than or equal to 20%, for example. Diffusion layer 40 is exemplified as but not limited to being made of a light diffusing material (fine particles) such as silica or calcium carbonate.

Diffusion layer 40 may further be adhesive. For example, diffusion layer 40 may be made of a highly transparent adhesive material such as an optical clear adhesive (OCA). In the present embodiment, diffusion layer 40 is adhesive and adheres to film 21 and transparent plate 30.

Diffusion layer 40 should be selected to have a refractive index close to at least one of transparent plate 30 and film 21. The thickness of diffusion layer 40 should be, for example, less than or equal to 0.5 mm.

Note that diffusion layer 40 need not be provided. For example, if moiré does not occur in the image displayed by display apparatus 100, or if the moiré is within an acceptable range, diffusion layer 40 may be omitted.

Display apparatus 100 may further include a transmittance adjustment layer implemented using a half mirror, a colored film, or colored glass. The transmittance adjustment layer is arranged, for example, between display 10 and decorative layer 20a. The half-mirror may, for example, consist of a metal film or transparent laminate film formed on a base material (for example, transparent plate 30). For example, when a metal film is used, the metal film is formed by depositing aluminum, silver, or tin or the like on the substrate by, for example, vapor deposition. The base material of the colored film and the colored glass is formed by kneading pigment or dye into, for example, the base material. The base material of the colored film is made of resin, and the base material of the colored glass is made of glass.

The transmittance adjustment layer reduces the amount of light that enters display apparatus 100 from the outside and reaches display 10, making display 10 less visible. The number of microholes 22a in base layer 22 can therefore be increased, which further enables display apparatus 100 to inhibit the blurring of images.

Controller 50 is a control apparatus that controls each element included in display apparatus 100. More specifically, controller 50 controls display 10 so as to switch display 10 between a non-display mode in which no images are displayed on display 10 and the decoration of decorative sheet 20 is visible to the user, and a display mode in which images are displayed on display 10. Controller 50 may, for example, include an input unit (not illustrated in the drawings) that accepts user inputs and performs the above control in response to user inputs obtained via the input unit.

Controller 50 is a microcomputer, but may be implemented by dedicated circuitry or the like. Controller 50 reads a control program from internal memory and executes the control program.

The luminance value of the image displayed on display apparatus 100 configured as described above depends mainly on the luminance value of the image on display 10 and the transmittance (for example, the parallel light transmittance) of decorative sheet 20.

The luminance value of the image displayed by display apparatus 100 should be 100 cd/m² or higher. Stated differently, the transmittance of decorative sheet 20 and the luminance value of the image light emitted from display 10 should be determined so that the luminance value of the image displayed on display apparatus 100 is 100 cd/m² or higher. The transmittance of decorative sheet 20, for example, depends mainly on the aperture ratio of base layer 22. For example, if the aperture ratio of base layer 22 is 20%, the luminance value of display 10 (luminance value of the image displayed on display surface 10a) should be 500 cd/m² or higher to achieve an image luminance of 100 cd/m² or higher.

The luminance value is exemplified here as the maximum value of luminance in the image displayed by display apparatus 100, but the luminance value is not limited to this example. The luminance value may be the minimum, average, or median value of the image displayed by display apparatus 100.

Although FIG. 1 illustrates an example in which display 10 and decorative sheet 20 are rectangular in shape, display 10 and decorative sheet 20 are not limited to being rectangular in shape. The front view shape of display 10 and decorative sheet 20 may be circular or polygonal, for example.

### [2. Haze Value Verification]

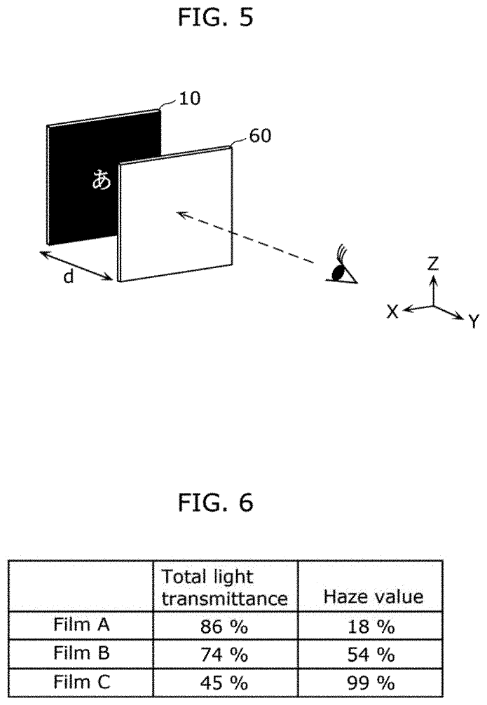

Next, further improvements to the images displayed by display apparatus 100 will be described with reference to FIG. 5 through FIG. 9. The image quality varies depending on the haze value of decorative sheet 20 and the distance between decorative sheet 20 and display 10. First, the haze value and distance at which characters can be read when display apparatus 100 displays characters and the like will be described. FIG. 5 is a diagram for illustrating a first experiment according to the present embodiment. FIG. 6 illustrates the characteristics of film 60 used in the first experiment according to the present embodiment. The haze value given below corresponds to the haze value of the entire decorative sheet 20. The haze value is, for example, an average value.

As illustrated in FIG. 5, the first experiment uses display 10 and film 60. Display 10 displays a target image (in the example in FIG. 5, the Japanese character “ [symbol] ”). Film 60 is a film that assumes the functions of decorative sheet 20. Whether or not the Japanese character “ [symbol] ” displayed by display 10 as a negative image (white character on a black background) was legible was determined while varying distance d between display 10 and film 60. Distance d was varied within a range of 0 to 10 mm. Distance d illustrated in FIG. 5 corresponds to distance d illustrated in FIG. 2. In other words, distance d corresponds to the distance between display 10 and decorative layer 20a of decorative sheet 20.

Based on JIS S 0032 (method for estimating minimum legible character size of Japanese characters), the character size was set to a font size of 8 (approximately 2.8 mm) and the font was set to MS Mincho. Note that legibility is based on visual evaluation (subjective evaluation) by the subject. As illustrated in FIG. 6, as film 60, the experiment was conducted using three different films A through C, each with a different total light transmittance and haze value. The three types of decorative sheets 20 were produced, for example, by screen printing transparent resin ink containing pigment on a 50 μm thick polyethylene terephthalate (PET) film.

The first experiment was conducted in a room with fluorescent lights. Display 10 is a 31-inch, 4K (4096×2160 pixel) resolution liquid crystal display. The output of display 10 is adjusted so that the luminance value of the image (“ [symbol] ”) displayed by display 10 is 200 to 250 cd/m². The space between display 10 and film 60 is an air layer. The subject looks at the character at a distance of 0.5 m from display 10 and determines if the character is legible.

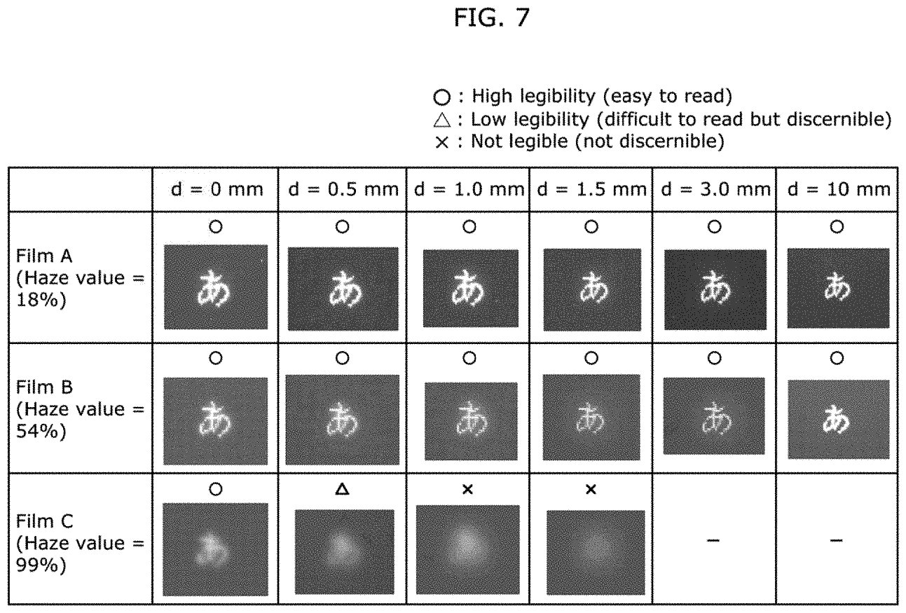

FIG. 7 illustrates the results of the first experiment according to the present embodiment. In FIG. 7, the circle indicates high legibility (the character is easy to read). The triangle indicates low legibility (the character is difficult to read but discernible). Both the circle and the triangle indicate that the character is legible. The X indicates not legible (not discernible).

As illustrated in FIG. 7, film A (haze value=18%) and film B (haze value=54%) are legible across the range of distance d=0 to 10 mm. Film C (haze value=99%) is legible across the range of distance d=0 to 0.5 mm. Note that the results for film 60 with a haze value greater than 54% and less than 55% are considered to be similar to the results for film B.

The haze value of decorative sheet 20 should therefore be less than 55%. For example, the haze value of decorative sheet 20 may be greater than or equal to 10% and less than 55%. Distance d is not restricted as long as it is within 10 mm.

The haze value of decorative sheet 20 may be greater than or equal to 55% if distance d is less than or equal to 0.5 mm. From the viewpoint of further improving legibility, the haze value of decorative sheet 20 should be greater than or equal to 55% and distance d should be 0 mm. When distance d is 0 mm, decorative sheet 20 and display 10 are directly attached to each other by the adhesive layer of one of decorative sheet 20 and display 10, without providing transparent plate 30 and diffusion layer 40.

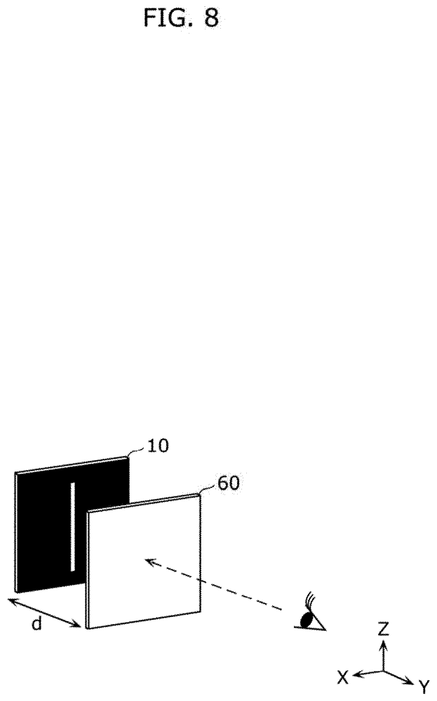

Next, the haze value and distance at which display apparatus 100 can inhibit the blurring of images displayed by display apparatus 100 will be described. FIG. 8 is a diagram for illustrating a second experiment according to the present embodiment.

As illustrated in FIG. 8, the second experiment uses display 10 and film 60. Display 10 displays a target image (in the example in FIG. 8, a white line pattern). The width (length in the lateral direction) of the white line pattern is 7 mm. Film 60 is the same film used in the first experiment. Whether or not the edge of the white line pattern (the boundary between the white line pattern and the black background) displayed by display 10 as a negative image (white line pattern on a black background) appeared blurry was determined while varying distance d between display 10 and film 60. Distance d was varied within a range of 0 to 4.0 mm. Whether the edge appeared blurry and whether the blurring is within the acceptable range is based on visual evaluation (subjective evaluation) by the subject. The environment of the second experiment is the same as the first experiment.

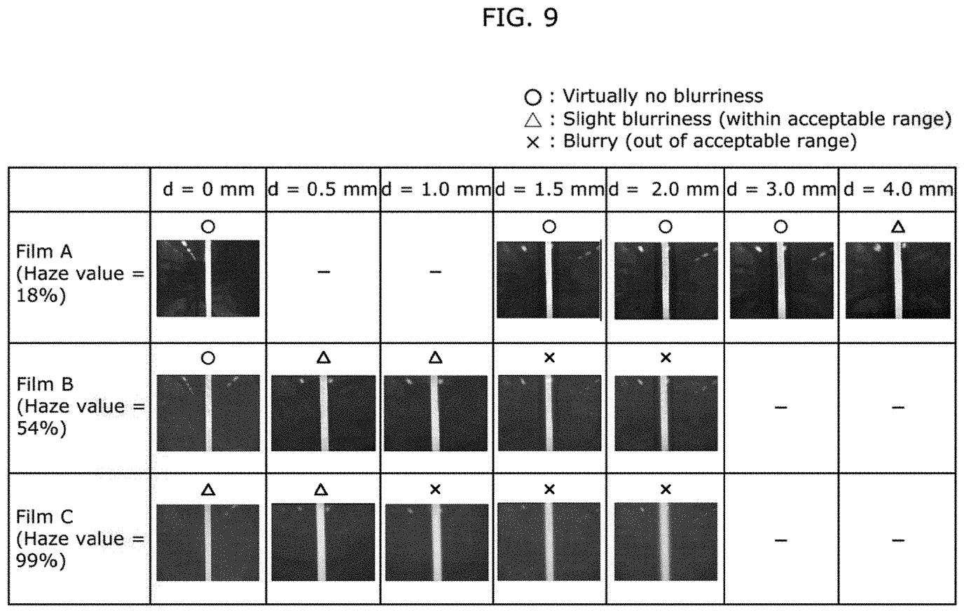

FIG. 9 illustrates the results of the second experiment according to the present embodiment. In FIG. 9, the circle means virtually no blurriness. The triangle means slight blurriness (within the acceptable range). Both the circle and the triangle mean the blurriness of the image is within the acceptable range. The X means blurry (out of the acceptable range).

As illustrated in FIG. 9, film A (haze value=18%) exhibits acceptable blurriness across distance d=0 to 4.0 mm. Film B (haze value=54%) exhibits acceptable blurriness across distance d=0 to 1.0 mm. Film C (haze value=99%) exhibits acceptable blurriness across distance d=0 to 0.5 mm. Note that the results for film 60 with a haze value greater than 18% and less than 20% are considered to be similar to the results for film A.

Therefore, from the viewpoint of inhibiting blurring of images, the haze value of decorative sheet 20 should be greater than or equal to 20% and less than 55%, and distance d should be less than or equal to 1.0 mm. From the viewpoint of further inhibiting blurring of images, distance d should be less than or equal to 0.5 mm. Even more preferably, distance d should be 0 mm.

From the viewpoint of inhibiting blurring of images, the haze value of decorative sheet 20 should be less than 20%, and distance d should be less than or equal to 4.0 mm. For example, when the haze value of decorative sheet 20 is greater than or equal to 10% and less than 20%, distance d may be less than or equal to 4.0 mm. From the viewpoint of further inhibiting blurring of images, distance d should be less than or equal to 3.0 mm.

The haze value of decorative sheet 20 may be greater than or equal to 55% if distance d is less than or equal to 0.5 mm.

By determining the haze value and distance d as described above, display apparatus 100 can display images of the same high quality as, for example, a television.

From the viewpoint of further improving image quality, the haze value of decorative sheet 20 should be less than 20%. From the viewpoint of further inhibiting blurring of image, the haze value of decorative sheet 20 should be less than or equal to 10%. Decorative sheet 20 may be realized with a half mirror, a colored film, or colored glass.

Decorative sheet 20 should have a haze value that inhibits display apparatus 100 or the interior of the object from being visible by outside light in both the display mode and the non-display mode. Decorative sheet 20 should have a haze value that provides a gloss similar to that of the object.

### [3. Manufacturing Method]

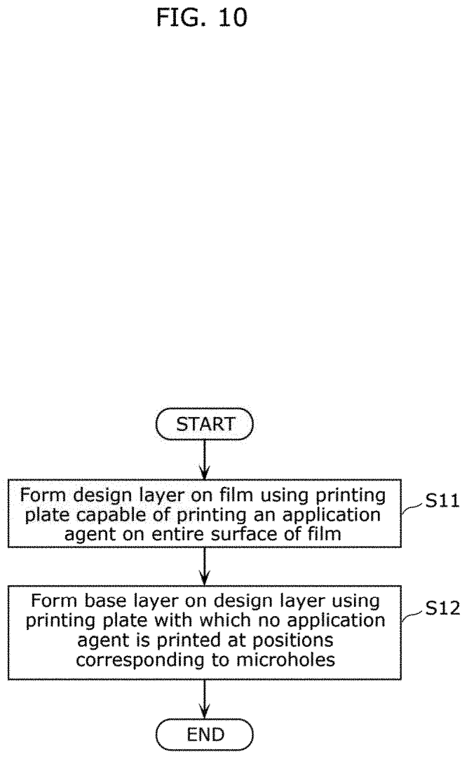

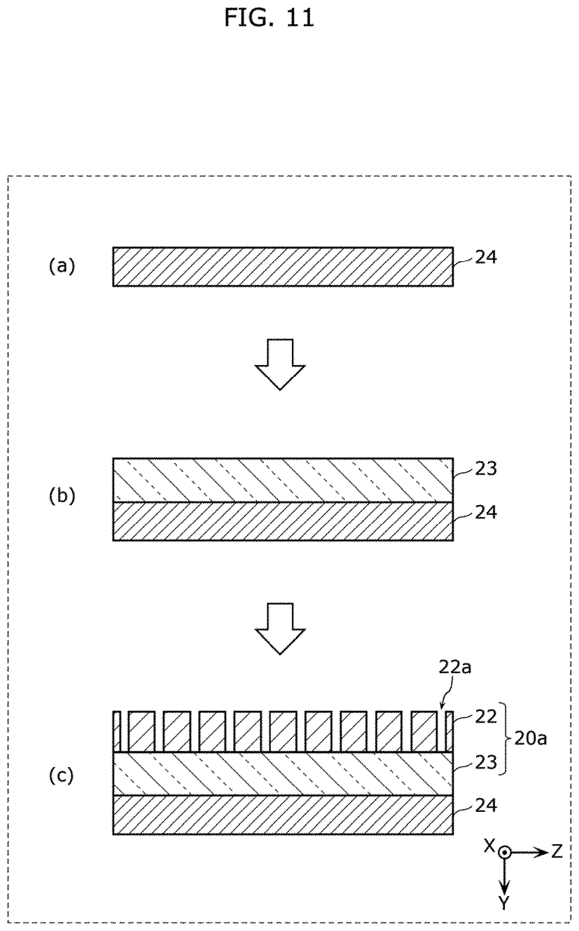

Next, the manufacturing method of decorative sheet 20 described above will be described with reference to FIG. 10 and FIG. 11. FIG. 10 is a flowchart illustrating one example of the manufacturing method of decorative sheet 20 according to the present embodiment. Specifically, FIG. 10 is a flowchart of the formation of decorative layer 20a on film 24. FIG. 11 is a diagram for illustrating one example of the manufacturing method of decorative sheet 20 according to the present embodiment. More specifically, FIG. 11 illustrates cross-sectional views of decorative sheet 20 in the process of being manufactured. In FIG. 11, (a) illustrates a cross-sectional view of one prepared film 24 (for example, film 24 divided into pieces according to the size of display apparatus 100). FIG. 11 also illustrates an example where design layer 23 is formed from a single layer.

As illustrated in FIG. 10, first, design layer 23 is formed on film 24 using a printing plate capable of printing an application agent (for example, a transparent resin ink containing pigment or paint) over the entire area of film 24 (S11). Stated differently, in step S11, design layer 23 is formed by printing on the entire surface of film 24 on the display surface 10 side. Design layer 23 formed in step S11 is formed in the region corresponding to image region R3 and peripheral region R4 of base layer 22.

Design layer 23 is formed by printing, for example, by gravure printing. If gravure printing is used, the printing plate is an intaglio plate in which the entire area corresponding to film 24 is a groove.

In FIG. 11, (b) illustrates a cross-sectional view of film 24 with design layer 23 formed in step S11. As illustrated in (b) in FIG. 11, design layer 23 is formed on the surface of film 24 on the display 10 side (i.e., the Y-axis negative side surface) without any breaks. For example, design layer 23 should be uniform in thickness.

Referring again to FIG. 10, next, base layer 22 is formed on design layer 23 using a printing plate with which no application agent (for example, ink containing pigment or paint) is printed at positions corresponding to microholes 22a (S12). Stated differently, in step S12, base layer 22 with microholes 22a is formed on design layer 23 by printing.

Base layer 22 is formed by printing, for example, by gravure printing. If gravure printing is used, the printing plate is an intaglio plate with no grooves formed at positions corresponding to microholes 22a. Stated differently, no application agent is poured into positions corresponding to microholes 22a in the printing plate.

As illustrated in (c) in FIG. 11, step S12 allows the formation of base layer 22 with microholes 22a on design layer 23. Base layer 22 is provided, for example, in contact with design layer 23.

As described above, design layer 23 and base layer 22 are formed on film 24 in this order. This allows base layer 22 with microholes 22a to be formed on design layer 23 by printing.

Next, a decorative sheet with microholes that penetrate the base layer and design layer will be described as a comparative example. Such a decorative sheet can be formed by physically processing (for example, laser processing) to form microholes after the base layer and design layer have been formed over the entire film surface. In this case, manufacturing costs increase due to the additional physical processing steps. Moreover, since the microholes penetrate the base layer and the design layer, there are concerns that durability (for example, water resistance) will be reduced and the viewing angle of the image will be narrowed.

The decorative sheet in the comparative example can also be formed by forming one of the base layer and design layer with microholes, and then forming the other of the base layer and design layer with microholes on top of the one of the base layer and design layer with microholes. In this case, the process is complicated by the need to align the microholes in the one of the base layer and the design layer with the microholes in the other of the base layer and the design layer (for example, the microholes must be aligned when the printing plate is arranged).

Decorative sheet 20 according to the present embodiment can be produced by simply replacing the printing plate for forming base layer 22 with a printing plate corresponding to microholes 22a, as described above. In other words, decorative sheet 20 can be produced with the same tact as when forming a typical decorative sheet (for example, a decorative sheet without microholes 22a). Therefore, in the manufacturing of decorative sheet 20, manufacturing costs are less likely to increase and the manufacturing process is less likely to become complicated.

In addition, with decorative sheet 20, since microholes 22a are formed only in base layer 22 among base layer 22 and design layer 23, it is possible to inhibit a reduction in design quality and durability of decorative sheet 20. Moreover, existing printing plates (for example, printing plates that can form design layer 23 over the entire film 24) can be used for design layer 23, which further inhibits an increase in manufacturing costs.

The above manufacturing method is merely one non-limiting example.

### [4. Application Examples]

Next, application examples of display apparatus 100 described above will be described with reference to FIG. 12A through FIG. 14B. The application examples described below are mere examples, and the objects for which display apparatus 100 is used are not limited to these examples.

FIG. 12A is a diagram for illustrating the non-display mode in Application Example 1 of display apparatus 100 according to the present embodiment. FIG. 12B is a diagram for illustrating the display mode in Application Example 1 of display apparatus 100 according to the present embodiment.

As illustrated in FIG. 12A and FIG. 12B, display apparatus 100 may be installed housed in a building material (for example, wall 200), which is one example of the object. In this case, the building material includes a body including a recess for storing display apparatus 100, and display apparatus 100 stored in the recess. The recess is for embedding display apparatus 100 into the building material.

Wall 200 has a wood tone pattern, for example. In this case, decorative sheet 20 is decorated with a wood tone. Wood tone decoration is one example of object-specific decoration. As illustrated in FIG. 12A, when controller 50 controls display 10 in the non-display mode, the user will see the wood tone decoration formed on decorative sheet 20. Stated differently, the appearance of display apparatus 100 harmonizes with the appearance of wall 200. This makes it difficult for display apparatus 100 to be seen embedded in wall 200. Stated differently, decorative sheet 20 can inhibit display apparatus 100 from being visible.

As illustrated in FIG. 12B, when controller 50 controls display 10 in the display mode, the user can see the images displayed by display 10. The user can, for example, see images that appear to be floating on wall 200. At this time, the decoration formed on decorative sheet 20 should not be visible by the user.

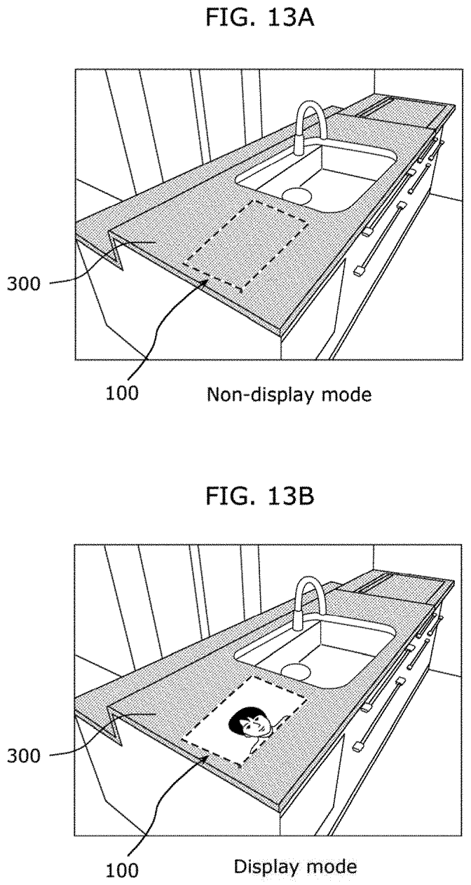

FIG. 13A is a diagram for illustrating the non-display mode in Application Example 2 of display apparatus 100 according to the present embodiment. FIG. 13B is a diagram for illustrating the display mode in Application Example 2 of display apparatus 100 according to the present embodiment.

As illustrated in FIG. 13A and FIG. 13B, display apparatus 100 may be installed housed in furniture (for example, kitchen counter 300), which is one example of the object. In this case, the furniture includes a body including a recess for storing display apparatus 100, and display apparatus 100 stored in the recess. The recess is for embedding display apparatus 100 into the furniture.

Kitchen counter 300 has a marble tone pattern, for example. In this case, decorative sheet 20 is decorated with a marble tone. Marble tone decoration is one example of object-specific decoration. As illustrated in FIG. 13A, when controller 50 controls display 10 in the non-display mode, the user will see the marble tone decoration formed on decorative sheet 20. Stated differently, the appearance of display apparatus 100 harmonizes with the appearance of kitchen counter 300. This makes it difficult for display apparatus 100 to be seen embedded in kitchen counter 300.

As illustrated in FIG. 13B, when controller 50 controls display 10 in the display mode, the user can see the images displayed by display 10. The user can, for example, see images that appear to be floating on kitchen counter 300. For example, display apparatus 100 displays video of, for example, a child's room so that the user can check on the child while cooking.

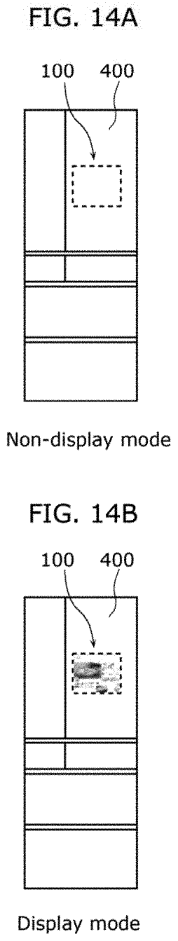

FIG. 14A is a diagram for illustrating the non-display mode in Application Example 3 of display apparatus 100 according to the present embodiment. FIG. 14B is a diagram for illustrating the display mode in Application Example 3 of display apparatus 100 according to the present embodiment.

As illustrated in FIG. 14A and FIG. 14B, display apparatus 100 may be installed housed in an electrical device (for example, a household electrical device such as refrigerator 400), which is one example of the object. In this case, the electrical device includes a body including a recess for storing display apparatus 100, and display apparatus 100 stored in the recess. The recess is for embedding display apparatus 100 into the electrical device.

For example, refrigerator 400 has a monochromatic color tone (for example, white). In this case, decorative sheet 20 is decorated with a white color tone. A white decoration is one example of object-specific decoration. As illustrated in FIG. 14A, when controller 50 controls display 10 in the non-display mode, the user will see the white decoration formed on decorative sheet 20. Stated differently, the appearance of display apparatus 100 harmonizes with the appearance of refrigerator 400. This makes it difficult for display apparatus 100 to be seen embedded in refrigerator 400.

As illustrated in FIG. 14B, when controller 50 controls display 10 in the display mode, the user can see the images displayed by display 10. The user can, for example, see images that appear to be floating on refrigerator 400. For example, cooking instructions or cooking ingredients can be displayed by display apparatus 100, allowing the user to cook efficiently.

### [5. Advantageous Effects, etc.]

As described above, display apparatus 100 according to the present embodiment includes: display 10 including display surface 10a on which an image is displayed; and decorative layer 20a that is arranged on the display surface 10a side of display 10 and includes base layer 22 and design layer 23 each formed to cover display surface 10a. Base layer 22 includes a light diffusing material, and a plurality of microholes 22a (one example of the openings) are formed through base layer 22. Design layer 23 is formed to cover the plurality of microholes 22a and non-opening portion 22b of base layer 22.

With this, display apparatus 100 can display images using light transmitted through microholes 22a formed in base layer 22. Light transmitted through microholes 22a is not diffused by non-opening portion 22b of base layer 22 (the portion including the light diffusing material), which makes it possible to achieve images with reduced blurring. Since design layer 23 covers microholes 22a and non-opening portion 22b of base layer 22, it is possible to inhibit a reduction in design quality compared to, for example, when only non-opening portion 22b of base layer 22 is covered, that is, when openings are formed through base layer 22 and design layer 23. Therefore, display apparatus 100 can inhibit a reduction in design quality as well as a reduction in image quality.

Non-opening portion 22b has a transmittance less than or equal to 5%.

With this, display apparatus 100 can inhibit light passing through non-opening portion 22b, i.e., inhibit diffused light from being emitted from display apparatus 100, which further inhibits blurring of images.

Base layer 22 includes image region R3 on display surface 10a in which the image is displayable, and peripheral region R4 in a periphery of image region R3. An aperture ratio of the plurality of microholes 22a1 in image region R3 and an aperture ratio of the plurality of microholes 22a2 in peripheral region R4 are equal.

With this, display apparatus 100 can inhibit differences in the appearance of image region R3 and peripheral region R4 when display 10 is not displaying images. In other words, display apparatus 100 can inhibit differences in the appearance of the decoration by decorative layer 20a. Therefore, display apparatus 100 can further inhibit a reduction in design quality.

A pitch of the plurality of microholes 22a formed in base layer 22 and a pitch of pixels included in display 10 are equal.

With this, display apparatus 100 can inhibit moiré caused by the plurality of microholes 22a in base layer 22 and the plurality of pixels in display 10. Therefore, display apparatus 100 can further inhibit a reduction in image quality.

Display apparatus 100 further includes diffusion layer 40 that diffuses light from display 10, between display 10 and decorative layer 20a.

With this, since display apparatus 100 can diffuse the image light before the image light from display 10 is incident on base layer 22 of decorative layer 20a, display apparatus 100 can inhibit moiré caused by the plurality of microholes 22a in base layer 22 and the plurality of pixels in display 10. Therefore, display apparatus 100 can further inhibit a reduction in image quality.

Display apparatus 100 further includes light-shielding layer 31 formed in a region corresponding to peripheral region R4, between display 10 and decorative layer 20a.

With this, when display 10 is not displaying images, display apparatus 100 can look closer in appearance to display 10 and the surroundings of display 10. In other words, display apparatus 100 can further inhibit display 10 from being visible when images are not being displayed. Therefore, display apparatus 100 can further inhibit a reduction in design quality.

Decorative layer 20a has a haze value greater than or equal to 55%, and a distance between decorative layer 20a and display 10 is less than or equal to 0.5 mm.

With this, display apparatus 100 can display high quality and legible images with minimal blurring even when the haze value is greater than or equal to 55%. By having a haze value greater than or equal to 55%, display apparatus 100 can inhibit display 10 and the like from being visible due to outside light incident on decorative layer 20a when display apparatus 100 is not displaying images.

Decorative layer 20a has a haze value less than 55%.

With this, display apparatus 100 can display legible images when display apparatus 100 displays characters and symbols as images. Display apparatus 100 can, for example, display legible images even when display 10 and decorative layer 20a are distanced apart by distance d (for example, when distanced within 10 mm apart).

Decorative layer 20a has a haze value less than 20%, and distance d between decorative layer 20a and display 10 is less than or equal to 4 mm.

With this, display apparatus 100 can display high quality images with minimal blurring even when the haze value is less than 20%. With display apparatus 100, distance d can be determined within a range of 4 mm or less, which increases the degree of freedom in regard to the thickness of each element. Thus, with this configuration, display apparatus 100 can inhibit blurring of images while further improving the degree of freedom in regard to the thickness of each element.

With display apparatus 100, other components can be arranged between decorative layer 20a and display 10 to improve the functionality of display apparatus 100. The “other components” should be determined appropriately according to the object in which display apparatus 100 is embedded, or the environment in which display apparatus 100 is used. For example, if display apparatus 100 is embedded in an object with a heat source nearby, such as a kitchen counter, an “other component” may be a light-transmissive, heat-resistant sheet. As another example, an “other component” may be a light-transmissive touch film that accepts inputs from the user.

Decorative layer 20a has a haze value greater than or equal to 20% and less than 55%, and a distance between decorative layer 20a and display 10 is less than or equal to 1 mm.

With this, display apparatus 100 can display high quality images with minimal blurring even when the haze value is greater than or equal to 20% and less than 55%. With display apparatus 100, distance d can be determined within a range of 1 mm or less, which increases the degree of freedom in regard to the thickness of each element. Thus, with this configuration, display apparatus 100 can inhibit blurring of images while improving the degree of freedom in designing the thickness of each element.

The image displayed on display surface 10a has a luminance greater than or equal to 500 cd/m².

With this, display apparatus 100 can display a bright image of 100 cd/m² or more, even when the aperture ratio of decorative layer 20a is 20%, for example. Thus, image quality is further improved.

Design layer 23 is a stacked structure of a plurality of pattern layers (for example, first design layer 23a, second design layer 23b, and third design layer 23c) each formed to cover display surface 10a, and a decorative pattern is formed on each of the plurality of pattern layers. Among the plurality of pattern layers, a microhole (one example of the opening) is not formed through at least one pattern layer, and among one or more pattern layers among the plurality of pattern layers excluding the at least one pattern layer, a microhole is formed through at least one pattern layer.

With this, for example, when display apparatus 100 includes a pattern layer that hinders transparency, display apparatus 100 can further improve the visibility of images by providing microholes in the pattern layer.

### Other Embodiments

Although the display apparatus according to an aspect of the present disclosure has been described based on the above embodiments, the display apparatus is not limited to the above embodiments.

Thus, the elements described in the accompanying drawings and the detailed description include not only elements essential to overcome the technical problem, but elements that are not necessarily essential to overcome the technical problem but are provided for the sake of exemplifying the techniques as well. As such, inclusion of these non-essential elements in the accompanying drawings and the detailed description should not be taken to mean that these non-essential elements are essential.

For example, in the above embodiment, microholes 22a in base layer 22 are described as constituting an air layer, but the present disclosure is not limited to this example. Microholes 22a may be filled, for example, with a resin that is light-transmissive and has substantially no light diffusing properties. The resin used should have a refractive index equal to that of film 21, for example. A resin that does not have light diffusing properties refers to a resin that does not contain light diffusing materials (fine particles) such as silica or calcium carbonate, but this example is non-limiting. Microholes 22a filled with such a resin are one example of a transmissive portion that transmits image light.

In the above embodiment, decorative sheet 20 is described as including a pair of films 21 and 24, but the present disclosure is limited to this example. Decorative sheet 20 may include a pair of light-transmissive plate-shaped members instead of the pair of films 21 and 24. In such cases, display apparatus 100 does not need to include transparent plate 30.

In the above embodiment, decorative sheet 20 is described as including film 21, base layer 22, design layer 23, film 24, and textured layer 25 stacked in this order from the display 10 side, but the stacking order is not limited to this example. For example, decorative sheet 20 may include film 21, base layer 22, film 24, design layer 23, and textured layer 25 stacked in this order from the display 10 side.

In the above embodiment, among base layer 22 and design layer 23, base layer 22 is described as arranged on the display 10 side, but the present disclosure is not limited to this example. Among base layer 22 and design layer 23, design layer 23 may be arranged on the display 10 side. In such cases, decorative sheet 20 may include film 21, design layer 23, base layer 22, film 24, and textured layer 25 stacked in this order from the display 10 side. Design layer 23 is formed on film 21 by, for example, printing.

In the above embodiment, display apparatus 100 is described as arranged embedded in an object, but display apparatus 100 is not limited to being embedded in an object. For example, display apparatus 100 may be arranged on the surface of an object (for example, the surface of a wall). For example, display apparatus 100 may be a wall-mounted display apparatus.

In the above embodiment, base layer 22 and design layer 23 are described as formed by printing, but base layer 22 and design layer 23 are not limited to this example.

In the above embodiment, base layer 22 is described as including pigment as a light diffusing material, but the light diffusing material is not limited to being achieved by the inclusion of pigment. For example, the light diffusing material may be fine particles of silica or calcium carbonate.

The image displayed by display 10 in the above embodiment is not particularly limited and may be TV video (for example, 4K TV quality), an icon display, or a segment display (for example, a seven-segment display).

The order of processes in the manufacturing method of decorative sheet 20 described in the above embodiment may be interchanged. The processes in the manufacturing method of decorative sheet 20 described in the above embodiment may be performed in one process or in separate processes. Here, “performed in one process” is intended to mean each process is performed using one apparatus, the processes are performed consecutively, or each process is performed at the same location. “In separate processes” is intended to mean each process is performed using a separate apparatus, each process is performed at different times (for example, different days), or each process is performed at a different location.

In the above embodiment, decorative sheet 20 (for example, decorative layer 20a) is described as arranged on the display 10 side of display apparatus 100, but decorative sheet 20 is not limited to being arranged on display apparatus 100. For example, decorative sheet 20 may be used in a light receiving apparatus such as a charge coupled device (CCD) or complementary metal oxide semiconductor (CMOS) camera, or in an apparatus combining a light receiving apparatus and display apparatus 100. A light receiving apparatus is one example of the optical functional unit. Stated differently, the optical functional unit may utilize light transmitted through decorative sheet 20. CCD and CMOS are examples of the light receiving unit.

The present disclosure can also be applied to optical devices such as elements that use outside light. Such an optical device is one including a decorative sheet and an element that uses light transmitted through the decorative sheet (an element that uses outside light). With the optical device according to the present disclosure, the above decorative sheet makes it more difficult to recognize elements that utilize light transmitted through the decorative sheet by preventing light reflected by, for example, the surface of elements that utilize light transmitted through the decorative sheet from reaching the outside of the optical device.

Decorative sheet 20 may be arranged directly on the surface of the element that utilizes the light transmitted through decorative sheet 20, and, alternatively, may be provided at predetermined intervals and arranged spaced apart.

The element that utilizes light transmitted through decorative sheet 20 is not particularly limited, and includes various elements such as imaging elements and sensors (light receiving sensors). Imaging elements and sensors are examples of the light receiving unit. The imaging elements and sensors may be arranged in a two-dimensional configuration in the XZ plane.

Such an optical device includes: an optical functional unit including at least one of display unit 10 that displays images or a light receiving unit that receives light; and decorative layer 20a that includes base layer 22 and design layer 23 each formed to cover the front surface of the optical functional unit, and is arranged on the front surface side of the optical functional unit. Base layer 22 includes a light diffusing material. A plurality of microholes 22a are formed through base layer 22. Design layer 23 is formed to cover the plurality of microholes 22a and non-opening portion 22b of base layer 22. The front surface is the surface on the decorative sheet 20 side of the optical functional unit, which is the surface on the Y-axis positive side.

For example, a display apparatus and a plurality of optical devices may be combined.

Various modifications to the above embodiments that may be conceived by those skilled in the art, as well as embodiments resulting from arbitrary combinations of elements and functions from different embodiments that do not depart from the essence of the present disclosure are included the present disclosure.

### INDUSTRIAL APPLICABILITY

The present disclosure is applicable to display apparatuses that are mounted to an object.

### REFERENCE SIGNS LIST

10 display

10a display surface

20 decorative sheet

20a decorative layer

21, 24 film

22 base layer

22a, 22a1, 22a2 microhole (opening)

22b non-opening portion

23 design layer

23a first design layer

23b second design layer

23c third design layer

25 textured layer

30 transparent plate

31 light-shielding layer

40 diffusion layer

50 controller

60, A, B, C film

100 display apparatus

200 wall (object)

300 kitchen counter (object)

400 refrigerator (object)

d distance

H height

p1, p2, p11, p12 pitch

R1 display region

R2 peripheral edge region

R3 image region

R3a, R4a region

R4 peripheral region

W width

1. A display apparatus comprising:
a display including a display surface on which an image is displayed; and
a decorative layer that is arranged on a display surface side of the display and includes a base layer and a design layer each formed to cover the display surface, wherein
the base layer includes a light diffusing material, and a plurality of openings are formed through the base layer, and
the design layer is formed to cover the plurality of openings and a non-opening portion of the base layer.

2. The display apparatus according to claim 1, wherein
the non-opening portion has a transmittance less than or equal to 5%.

3. The display apparatus according to claim 1, wherein
the base layer includes an image region on the display surface in which the image is displayable, and a peripheral region in a periphery of the image region, and
an aperture ratio of the plurality of openings in the image region and an aperture ratio of the plurality of openings in the peripheral region are equal.

4. The display apparatus according to claim 1, wherein
a pitch of the plurality of openings formed in the base layer and a pitch of pixels included in the display are equal.

5. The display apparatus according to claim 1, further comprising:
a diffusion layer that diffuses light from the display, between the display and the decorative layer.

6. The display apparatus according to claim 3, further comprising:
a light-shielding layer formed in a region corresponding to the peripheral region, between the display and the decorative layer.

7. The display apparatus according to claim 1, wherein
the decorative layer has a haze value greater than or equal to 55%, and a distance between the decorative layer and the display is less than or equal to 0.5 mm.

8. The display apparatus according to claim 1, wherein
the decorative layer has a haze value less than 55%.

9. The display apparatus according to claim 1, wherein
the decorative layer has a haze value less than 20%, and a distance between the decorative layer and the display is less than or equal to 4 mm.

10. The display apparatus according to claim 1, wherein
the decorative layer has a haze value greater than or equal to 20% and less than 55%, and a distance between the decorative layer and the display is less than or equal to 1 mm.

11. The display apparatus according to claim 1, wherein
the image displayed on the display surface has a luminance greater than or equal to 500 cd/m².

12. The display apparatus according to claim 1, wherein
the design layer is a stacked structure of a plurality of pattern layers each formed to cover the display surface,
a decorative pattern is formed on each of the plurality of pattern layers,
among the plurality of pattern layers, an opening is not formed through at least one pattern layer, and
among one or more pattern layers among the plurality of pattern layers excluding the at least one pattern layer, an opening is formed through at least one pattern layer.

13. An optical device comprising:
an optical functional unit including at least one of a display that displays an image or a light receiving unit configured to receive light; and
a decorative layer that includes a base layer and a design layer each formed to cover a front surface of the optical functional unit, and is arranged on a front surface side of the optical functional unit, wherein
the base layer includes a light diffusing material, and a plurality of openings are formed through the base layer, and
the design layer is formed to cover the plurality of openings and a non-opening portion of the base layer.
